(19) United States
(12) Patent Application Publication
(10) Pub. No.: US 2022/0089477 A1
(43) Pub. Date: Mar. 24, 2022

(54) COVER WINDOW, METHOD OF MANUFACTURING THE SAME, AND DISPLAY DEVICE INCLUDING THE SAME

(71) Applicant: Samsung Display Co., Ltd., Yongin-si (KR)

(72) Inventors: Dongsung LEE, Yongin-si (KR); Jihyun KO, Yongin-si (KR); Seungho KIM, Yongin-si (KR); Hyunseung SEO, Yongin-si (KR); Hyunkyung YUN, Yongin-si (KR)

(21) Appl. No.: 17/223,960

(22) Filed: Apr. 6, 2021

(30) Foreign Application Priority Data
Sep. 21, 2020 (KR) 10-2020-0121795

(51) Int. Cl. C03C 17/30; H01L 51/52; C03B 23/03

(52) U.S. Cl. CPC C03C 17/30; H01L 27/3244; C03B 23/0302; H01L 51/5237

(57) ABSTRACT

Methods of manufacturing a curved cover window of the disclosure prevent or reduce damage to a window substrate of the curved cover window. Methods include manufacturing methods in which a hard coating layer is formed on a window substrate, and optionally molding the window substrate on which the coating layer is formed in a manner as to minimize or reduce breaking or damage to the window substrate. By using a hard coating layer which is harder than the window substrate and which may include a first polycarbonate layer, a second polymethyl methacrylate layer, and polysilsesquioxane; and thermally molding the window substrate and hard coating layer at a temperature of about 120° C. to about 130° C. and for about three minutes to about five minutes; rupture of the window substrate during the molding process can be reduced.

### CROSS-REFERENCE TO RELATED APPLICATION

This patent application claims priority to and the benefit of Korean Patent Application No. 10-2020-0121795, filed on Sep. 21, 2020, in the Korean Intellectual Property Office, the entire content of which is incorporated by reference.

### FIELD

Embodiments of the present disclosure relate to a cover window, manufacturing methods, and a display device including the same, and, for example, to a cover window having increased product reliability, a method of manufacturing the cover window, and a display device including the cover window.

### BACKGROUND

Mobility-based display devices are widely used in various forms, and these display devices may include a display panel that provides images and a cover window that protects the display panel.

Recently, cover windows having at least one curved portion for flexible display devices have been developed.

### SUMMARY

One or more embodiments of the present disclosure include methods of manufacturing a cover window which prevent or reduce breaking or damage to the window substrate, methods in which a hard coating layer is formed on a window substrate, and methods which may include molding the window substrate on which the coating layer is formed in a manner as to minimize or reduce breaking or damage to the window substrate.

Additional aspects of embodiments will be set forth in part in the description which follows and, in part, will be apparent from the description, or may be learned by practice of the presented embodiments of the disclosure.

According to embodiments of the present disclosure, methods of manufacturing a cover window including at least one flat portion and at least one curved portion are disclosed. The methods include forming a hard coating layer having a thickness of about 20 μm to about 50 μm on a first surface of a window substrate, and molding the window substrate on which the hard coating layer is formed, wherein at least one first flat portion and at least one first curved portion are formed in the window substrate during the molding of the window substrate.

The forming of the hard coating layer on the first surface of the window substrate may also include forming a first layer including polycarbonate and a second layer on the first layer and including polymethyl methacrylate.

The first layer may have a thickness of about 550 μm to about 880 μm.

The second layer may have a thickness of about 30 μm to about 60 μm.

In the forming of the hard coating layer on the first surface of the window substrate, the hard coating layer may further include polysilsesquioxane.

The polysilsesquioxane may have a viscosity of about 10 centipoise (cP) to about 30 cP.

In the forming of the hard coating layer on the first surface of the window substrate, a hardness of the hard coating layer may be higher than a hardness of the window substrate.

The method may further include, after the forming of the hard coating layer on the first surface of the window substrate, forming a light blocking member on the second surface of the window substrate opposite the first surface of the window substrate.

The molding process of the window substrate, on which the hard coating layer is formed, may include thermally forming the window substrate at a temperature of about 120° C. to about 130° C. and for about three minutes to about five minutes.

The molding of the window substrate may further include forming at least one second flat portion and at least one second curved portion in the hard coating layer.

The method may further include, after the molding of the window substrate on which the hard coating layer is formed, forming a functional coating layer on the hard coating layer.

Also disclosed is a cover window manufactured according to embodiments of the present disclosure. The cover window may include at least one flat portion and at least one curved portion, a window substrate including at least one first flat portion and at least one first curved portion, and a hard coating layer including at least one second flat portion and at least one second curved portion, the hard coating layer being on a first surface of the window substrate and having a thickness of about 20 μm to about 50 μm.

The window substrate may include a first layer including polycarbonate and a second layer including polymethyl methacrylate on the first layer.

The first layer may have a thickness of about 550 μm to about 880 μm.

The second layer may have a thickness of about 30 μm to about 60 μm.

The hard coating layer may also include polysilsesquioxane.

A hardness of the hard coating layer may be higher than a hardness of the window substrate.

The cover window may further include a functional coating layer on the hard coating layer.

The cover window may further include a lower coating layer on a second surface of the window substrate opposite the first surface of the window substrate.

According to one or more embodiments, a display device includes a display panel, and a cover window above the display panel and including at least one flat portion and at least one curved portion, wherein the cover window includes a window substrate having at least one first flat portion and at least one first curved portion, and a hard coating layer including at least one second flat portion and at least one second curved portion, the hard coating layer being on a first surface of the window substrate and having a thickness of about 20 μm to about 50 μm.

Other aspects and features of embodiments of the present disclosure other than those described above will become apparent from the accompanying drawings, the appended claims, and the detailed description of the disclosure.

### BRIEF DESCRIPTION OF THE DRAWINGS

The above aspects and features of one or more embodiments will be more apparent from the following description taken in conjunction with the accompanying drawings, in which:

FIG. 1 is a perspective view schematically illustrating a cover window according to one or more embodiments;

FIG. 2 is a cross-sectional view schematically illustrating a cover window according to one or more embodiments;

FIG. 3 is an enlarged cross-sectional view of portion A of FIG. 2;

FIG. 4 is a cross-sectional view schematically illustrating a display device according to one or more embodiments;

FIG. 5 is a cross-sectional view schematically illustrating a display panel according to one or more embodiments;

FIG. 6 is a cross-sectional view schematically illustrating methods of manufacturing a cover window of one or more embodiments;

FIG. 7 is a cross-sectional view schematically illustrating methods of manufacturing a cover window of one or more embodiments;

FIG. 8 is a cross-sectional view schematically illustrating methods of manufacturing a cover window of one or more embodiments;

FIG. 9 is a cross-sectional view schematically illustrating methods of manufacturing a cover window of one or more embodiments; and

FIG. 10 is a cross-sectional view schematically illustrating methods of manufacturing a cover window of one or more embodiments.

### DETAILED DESCRIPTION

Reference will now be made in more detail to embodiments, examples of which are illustrated in the accompanying drawings, wherein like reference numerals refer to like elements throughout. In this regard, embodiments of the present disclosure may have different forms and should not be construed as being limited to the descriptions set forth herein. Accordingly, the embodiments are merely described below, by referring to the figures, to explain aspects of embodiments of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Since the subject matter of the present disclosure may have various modifications and several embodiments, embodiments are shown in the drawings and will be described in more detail. The effects and features of embodiments of the present disclosure, and ways to achieve them will become apparent by referring to embodiments that will be described in more detail with reference to the drawings. However, the subject matter of the present disclosure is not limited to the following embodiments but may be embodied in various forms.

It will be understood that although the terms “first,” “second,” etc. may be used herein to describe various components, these components should not be limited by these terms. These components are only used to distinguish one component from another.

In the embodiments below, the singular forms include the plural forms unless the context clearly indicates otherwise.

In the present specification, it is to be understood that the terms such as “including” or “having” are intended to indicate the existence of the features or components disclosed in the specification, and are not intended to preclude the possibility that one or more other features or components may be added.

In the embodiments below, it will be understood when a portion such as a layer, an area, or an element is referred to as being “on” or “above” another portion, it can be directly on or above the other portion, or intervening portion may also be present.

Also, in the drawings, for convenience of description, sizes of elements may be exaggerated or contracted. For example, since sizes and thicknesses of components in the drawings may be arbitrarily illustrated for convenience of explanation, the following embodiments are not limited thereto.

In the present specification, “A and/or B” refers to A, B, or A and B. In addition, in the present specification, “at least one of A and B” refers to A, B, or A and B.

In the following embodiments, the expression that a line “extending in a first direction or a second direction” includes not only a line extending in a linear form but also extending in a zigzag or curved shape in the first or second direction.

In the following embodiments, the expression “on a plane” or “in a plane” indicates that an object is viewed from above, and the expression “on a cross-section” or “in a cross-section” indicates that a cross-section of the object cut vertically is viewed from a side. In the following embodiments, the expression “overlapping” includes overlapping “on a plane” and “on a cross-section.”

Embodiments of the present disclosure will be described below in more detail with reference to the accompanying drawings. Those components that are the same or are in correspondence are rendered the same reference numerals regardless of the figure number.

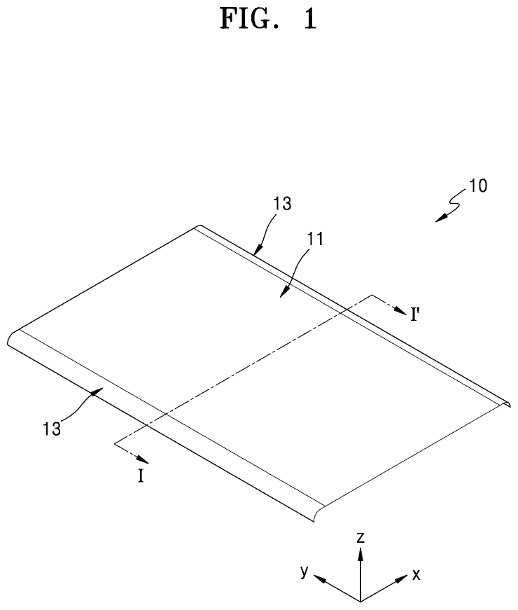

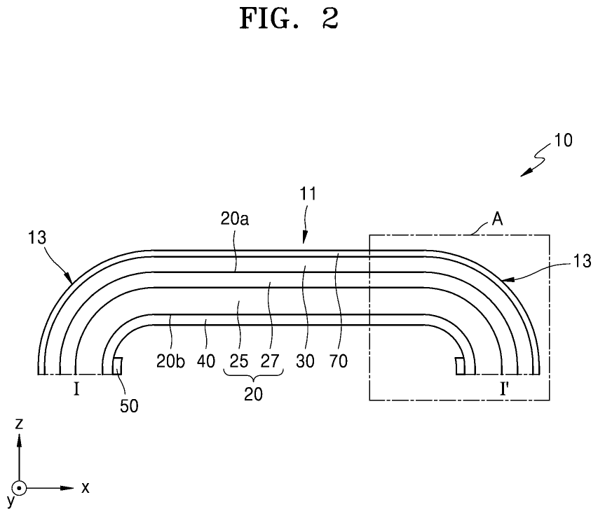

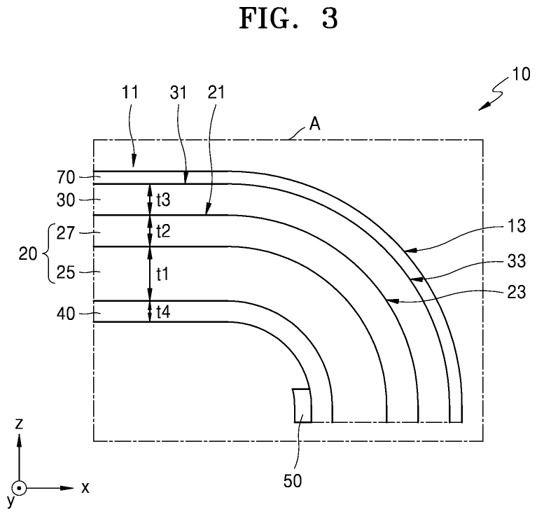

FIG. 1 is a perspective view schematically illustrating a cover window of one or more embodiments. FIG. 2 is a cross-sectional view schematically illustrating a cover window of one or more embodiments, and is a cross-sectional view of the cover window taken along line I-I′ of FIG. 1. FIG. 3 is an enlarged cross-sectional view of portion A of FIG. 2.

Referring to FIGS. 1 through 3 a cover window 10 may include at least one flat portion 11 and at least one curved portion 13. The flat portion 11 may be a portion of the cover window, the portion having a flat upper surface. The curved portion 13 may be at least a portion of the cover window 10 that is curved along the z axis.

The cover window 10 may include the flat portion 11 formed in a part of the cover window 10, and two curved portions 13 that are spaced apart from each other in an x-direction, with the flat portion 11 therebetween. However, various other modifications may be made; for example, there may be one curved portion 13 or three curved portions 13 in the cover window 10.

In one or more embodiments, curved portions that are spaced apart from each other in a y-direction may be further included, with the flat portion 11 formed in a portion of the cover window 10 therebetween.

As is illustrated in FIG. 2, the cover window 10 may include a window substrate 20 and a hard coating layer 30 on first surface 20a of the window substrate 20. Also, the cover window 10 may further include a lower coating layer 40 on the second surface 20b opposite the first surface 20a of the window substrate 20.

The window substrate 20 may include a polymer resin. In more detail, the window substrate 20 may include at least one material from the group including polyethersulfone, polyacrylate, polyether imide, polyethylene naphthalate, polyethylene terephthalate, polyphenylene sulfide, polyarylate, polyimide, polycarbonate, cellulose triacetate, cellulose acetate propionate, polyarylene ether sulfone, benzocyclobutene, hexamethyldisiloxane, and/or polymethyl methacrylate.

As is illustrated in FIG. 3, the window substrate 20 may include at least one first flat portion 21 and at least one first curved portion 23. The flat portion 11 of the cover window 10 may correspond to the first flat portion 21 of the window substrate 20, and the curved portion 13 of the cover window 10 may correspond to the first curved portion 23 of the window substrate 20.

As the cover window 10 includes the window substrate 20, the at least one first flat portion 21, and the at least one first curved portion 23, which are formed in the window substrate 20; it may be understood that the flat portion 11 and the curved portion 13 corresponding to the window substrate 20 are formed in the cover window 10, including the window substrate 20 which is also in the cover window 10.

As will be further described below, as the window substrate 20 is molded using a mold, and the at least one first flat portion 21 and the at least one first curved portion 23 may be formed in the window substrate 20. This will be described in further detail in regard to methods of manufacturing a cover window.

The window substrate 20 may include a first layer 25 and a second layer 27. In one embodiment, the second layer 27 may have a greater hardness than the first layer 25. In another embodiment, the first layer 25 of the window substrate 20 may include polycarbonate (PC), and the second layer 27 of the window substrate 20 may include polymethyl methacrylate (PMMA).

The first layer 25 and the second layer 27 of the window substrate 20 may both include PC. The second layer 27 may include PC having a reinforced hardness compared to that of the first layer 25.

The first layer 25 of the window substrate 20 may have a first thickness t1. The first thickness t1 of the first layer 25 may be about 550 μm to about 800 μm. When the first thickness t1 of the first layer 25 is less than 550 μm, bending properties of the cover window 10 may be degraded. On the other hand, when the first thickness t1 of the first layer 25 is greater than 800 μm, the hardness of the cover window 10 may be lowered. Thus, when the first thickness t1 of the first layer 25 is about 550 μm to about 800 μm, the bending properties of the cover window 10 may be improved, thereby enhancing the molding properties of the cover window 10 and preventing or reducing cracks in the curved portion, at the same time.

The second layer 27 of the window substrate 20 may have a second thickness t2. The second thickness t2 of the second layer 27 may be about 30 μm to about 60 μm. When the second thickness t2 of the second layer 27 is less than 30 μm, the hardness of the cover window 10 may be lowered. On the other hand, when the thickness the second thickness t2 of the second layer 27 is greater than 60 μm, the window substrate 20 may break during a process of molding the window substrate 20. Thus, when the second thickness t2 of the second layer 27 is about 30 μm to about 60 μm, the molding properties of the cover window 10 may be improved, and breaking of the window substrate 20 during molding of the cover window 10 may be prevented or reduced.

The second layer 27 may also include high hardness PC, and the second layer 27 may have a thickness of about 50 μm to about 100 μm.

When the window substrate 20 includes glass, and the window substrate 20 is molded to form at least one curved portion in the window substrate 20, the window substrate 20 may break, for example.

In one or more embodiments, where the window substrate 20 is manufactured using a polymer resin, when forming at least one curved portion by molding the window substrate 20, breaking of or damage to the window substrate 20 may be prevented or reduced.

The window substrate 20 may include a first layer 25 including PC and a second layer 27 including PMMA, which may prevent or reduce breaking of or damage to the window substrate 20, even when forming at least one curved portion in the window substrate 20 by molding the same.

The hard coating layer 30 may be on the first surface 20a of the window substrate 20. In a present embodiment, the hard coating layer 30 may have a greater hardness than the window substrate 20. For example, the hard coating layer 30 may be on the window substrate 20 to increase a low surface hardness of the window substrate 20. In an embodiment, a hardness of the hard coating layer 30 may be equal to or smaller than that of the window substrate 20.

In a present embodiment, the hard coating layer 30 may include at least one second flat portion 31 and at least one second curved portion 33. The flat portion 11 of the cover window 10 may correspond to the second flat portion 31 of the hard coating layer 30, and the curved portion 13 of the cover window 10 may correspond to the second curved portion 33 of the hard coating layer 30.

In embodiments where the cover window 10 includes the hard coating layer 30, and when the at least one second flat portion 31 and the at least one second curved portion 33 are formed in the hard coating layer 30; it may be understood that the flat portion 11 and the curved portion 13 corresponding to the hard coating layer 30 are formed in the cover window 10, including the hard coating layer 30.

As will be further described below, the at least one second flat portion 31 and the at least one second curved portion 33 may be formed in the hard coating layer 30 as the window substrate 20 on which the hard coating layer 30 is formed is molded using a mold. This will be described in further detail in regard to a method of manufacturing a cover window.

In one or more embodiments, the hard coating layer 30 may have a third thickness t3. The third thickness t3 of the hard coating layer 30 may be about 20 μm to about 50 μm. When the third thickness t3 of the hard coating layer 30 is less than 20 μm, the hardness of the cover window 10, including the hard coating layer 30, may be lowered. On the other hand, when the third thickness t3 of the hard coating layer 30 is greater than 50 μm, at least one of the hard coating layer 30 and/or the window substrate 20 may break in a process of molding the window substrate 20, on which the hard coating layer 30 is formed.

Accordingly, when the third thickness t3 of the hard coating layer 30 is about 20 μm to about 50 μm, the cover window 10 may have a hardness of 3H or greater, or 4H or greater, and the molding properties of the cover window 10 may be improved at the same time.

In one or more embodiments, the hard coating layer 30 may include polysilsesquioxane, and the polysilsesquioxane included in the hard coating layer 30 may have a ladder or ladder-like structure. As the polysilsesquioxane included in the hard coating layer 30 may have a ladder or ladder-like structure, the hard coating layer 30 may have thermoplastic properties, high heat resistance, excellent mechanical properties, and/or high light transmittance, and the molecular weight and structure thereof may be easily controlled.

In one or more embodiments, the hard coating layer 30 may have a low viscosity. For example, the polysilsesquioxane of the hard coating layer 30 may have a viscosity of about 10 cP to about 30 cP. As the hard coating layer 30 may have a low viscosity, the hard coating layer 30 may be formed flat on the window substrate 20.

In an embodiment when the second layer 27 includes high hardness PC, the hard coating layer 30 may include an acrylic polymer material.

The lower coating layer 40 may be on the second surface 20b of the window substrate 20, opposite the first surface 20a of the window substrate 20. In one or more embodiments, a hardness of the lower coating layer 40 may be greater than that of the window substrate 20. In other embodiments, a hardness of the lower coating layer 40 may be equal to or smaller than that of the window substrate 20.

In one or more embodiments, the lower coating layer 40 may have a fourth thickness t4. The fourth thickness t4 of the lower coating layer 40 may be about 10 μm. In certain embodiments, the lower coating layer 40 may be omitted.

The lower coating layer 40 may be on a second surface 20b of the window substrate 20 to protect the window substrate 20 from external impurities. In addition, the lower coating layer 40 may also protect a display panel below it from external impurities.

A light blocking member 50 may be under the lower coating layer 40. The light blocking member 50 may include a black matrix. In one or more embodiments, the black matrix may include at least one of a black pigment, a black dye, or black particles. In addition, the black matrix may include, for example, Cr and/or CrO_{X}, Cr/CrO_{X}, Cr/CrO_{X}/CrN_{Y}, a resin (carbon pigment, RGB mixed pigment), graphite, and/or a Non-Cr-based material, and/or the like.

In certain embodiments, the light blocking member 50 including a black matrix may be arranged to correspond to a non-display area of a display panel below the light blocking member 50. As the light blocking member 50 is arranged to correspond to the non-display area of the display panel below the light blocking member 50, components in the non-display area of the display panel may be prevented from being viewed by users, or their visibility to users may be reduced.

In additional embodiments, the light blocking member 50 may surround an outer portion of the cover window 10. In other embodiments, the light blocking member 50 may have a hole corresponding to a display area of the display panel below the light blocking member 50.

A functional coating layer 70 may be located on the hard coating layer 30. The functional coating layer 70 may be an anti-fingerprint (AF) coating layer, also referred to as an oleophobic coating layer. In more detail, the functional coating layer 70 may protect the window substrate 20 and the hard coating layer 30 below from external impurities, and prevent or reduce scratches in a low-frictional layer, imparting a slipping feeling to increase touch sensitivity, and an angle of contact.

In one or more embodiments, the functional coating layer 70 may be formed on the hard coating layer 30 by pre-processing steps such as irradiating plasma or electronic beaming (E-beam) a surface of the hard coating layer 30.

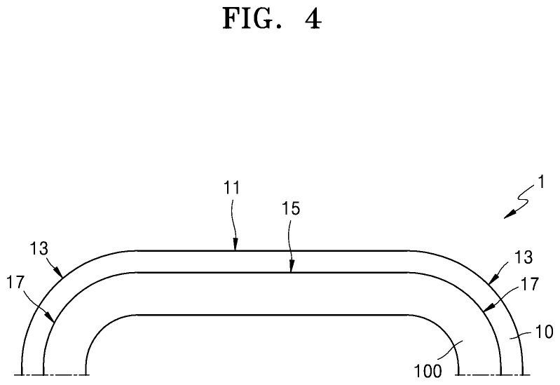

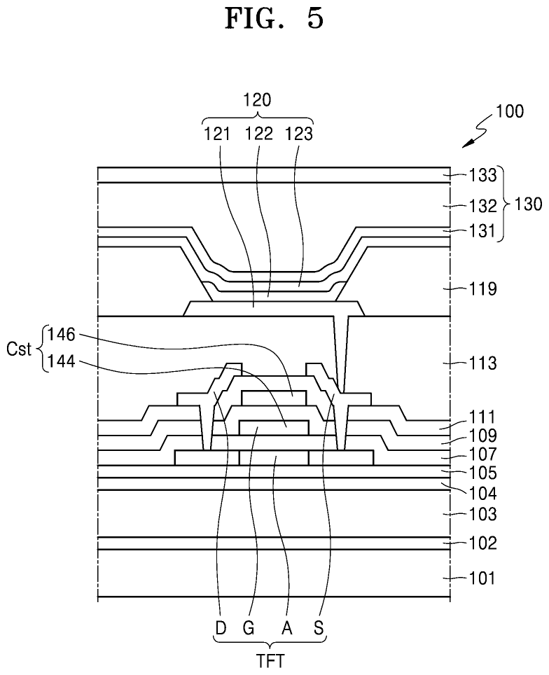

FIG. 4 is a cross-sectional view schematically illustrating a display device according to one or more embodiments. FIG. 5 is a cross-sectional view schematically illustrating a display panel according to one or more embodiments.

Referring to FIGS. 4 and 5, a display device 1 may include a display panel 100 and a cover window 10 on the display panel 100. The cover window 10 may be on the display panel 100 to protect the display panel 100 from external impurities.

In an embodiment, at least a portion of each of the display panel 100 and the cover window 10 may be curved. In detail, the display panel 100 and the cover window 10 may each include at least one flat portion and at least one curved portion.

As the display panel 100 includes at least one flat portion 15 and at least one curved portion 17, an image may be provided not only on a front surface or a rear surface of the display panel 100 but also on a side surface of the display panel 100. Thus, usability of the display device 1 may be increased.

Hereinafter, a stack structure of the display panel 100 will be briefly described with reference to FIG. 5.

The display panel 100 may include a first substrate 101, a first barrier layer 102, a second substrate 103, and a second barrier layer 104 that are sequentially stacked. The first substrate 101 and the second substrate 103 may include a polymer resin having high heat resistance. For example, the first substrate 101 and the second substrate 103 may include at least one material selected from the group including polyethersulfone, polyacrylate, polyether imide, polyethylene naphthalate, polyethylene terephthalate, polyphenylene sulfide, polyarylate, polyimide, polycarbonate, cellulose triacetate, cellulose acetate propionate, and/or polyarylene ether sulfone. In certain embodiments, the first substrate 101 and the second substrate 103 may include polyimide.

The first barrier layer 102 may be between the first substrate 101 and the second substrate 103. The first barrier layer 102 may be on the first substrate 101 to reduce or block penetration of foreign substances, moisture, and/or external air from below.

The second barrier layer 104 may be on the second substrate 103. The second barrier layer 104 may be on the second substrate 103 to reduce or block penetration of foreign substances, moisture, and/or external air from below.

The first barrier layer 102 and the second barrier layer 104 may include an inorganic insulating material such as silicon oxide (SiO_{X}), silicon nitride (SiN_{X}), silicon oxynitride (SiO_{X}N_{Y}), aluminum oxide (Al₂O₃), titanium oxide (TiO₂), tantalum oxide (Ta₂O₅), hafnium oxide (HfO₂), and/or zinc oxide (ZnO₂), and/or the like. In some embodiments, the first barrier layer 102 and the second barrier layer 104 may include the same material. For example, the first barrier layer 102 and the second barrier layer 104 may include silicon oxide (SiO_{X}). In other embodiments, the first barrier layer 102 and the second barrier layer 104 may include different materials. In yet additional embodiments, the first barrier layer 102 and/or the second barrier layer 104 may be omitted.

A buffer layer 105 may be on the second barrier layer 104. The buffer layer 105 may be above the first substrate 101 and the second substrate 103 to reduce or block penetration of foreign substances, moisture, and/or external air from below and provide a flat upper surface.

The buffer layer 105 may include an inorganic insulating material such as silicon oxide (SiO_{X}), silicon oxynitride (SiO_{X}N_{Y}), aluminum oxide (Al₂O₃), titanium oxide (TiO₂), tantalum oxide (Ta₂O₅), hafnium oxide (HfO₂), and/or zinc oxide (ZnO₂), and/or other like materials.

In one or more embodiments, the buffer layer 105 may include a first buffer layer and a second buffer layer. In certain embodiments, the first buffer layer and the second buffer layer may include a same material. In other embodiments, the first buffer layer and the second buffer layer may include different materials.

A thin film transistor TFT and a storage capacitor Cst may be on the buffer layer 105. The thin film transistor TFT may include a semiconductor layer A, a gate electrode G, a source electrode S, and a drain electrode D. The storage capacitor Cst may include a lower electrode 144 and an upper electrode 146.

In one or more embodiments, the semiconductor layer A may be on the buffer layer 105 and may include polysilicon. In other embodiments, the semiconductor layer A may include amorphous silicon. In additional embodiments, the semiconductor layer A may include an oxide of at least one material selected from the group including indium (In), gallium (Ga), stannum (Sn), zirconium (Zr), vanadium (V), hafnium (Hf), cadmium (Cd), germanium (Ge), chromium (Cr), titanium (Ti), and/or zinc (Zn). The semiconductor layer A may include a channel area and a source area and a drain area which may be doped with impurities.

A first insulating layer 107 may be included to cover the semiconductor layer A. The first insulating layer 107 may include an inorganic insulating material such as silicon oxide (SiO_{X}), silicon nitride (SiN_{X}), silicon oxynitride (SiO_{X}N_{Y}), aluminum oxide (Al₂O₃), titanium oxide (TiO₂), tantalum oxide (Ta₂O₅), hafnium oxide (HfO₂), and/or zinc oxide (ZnO₂), and/or the like. The first insulating layer 107 may be a single layer or multiple layers including the above-described inorganic insulating material.

The gate electrode G may be on the first insulating layer 107 to overlap the semiconductor layer A. The gate electrode G may include molybdenum (Mo), aluminum (Al), copper (Cu), titanium (Ti), and/or the like, and may include a single layer or multiple layers. In some embodiments, the gate electrode G may be a single layer of molybdenum (Mo).

A second insulating layer 109 may cover the gate electrode G. The second insulating layer 109 may include an inorganic insulating material such as silicon oxide (SiO_{X}), silicon nitride (SiN_{X}), silicon oxynitride (SiO_{X}N_{Y}), aluminum oxide (Al₂O₃), titanium oxide (TiO₂), tantalum oxide (Ta₂O₅), hafnium oxide (HfO₂), zinc oxide (ZnO₂), and/or the like. The second insulating layer 109 may be a single layer or multiple layers including the above-described inorganic insulating material.

The upper electrode 146 of the storage capacitor Cst may be on the second insulating layer 109. The upper electrode 146 may overlap the gate electrode G below the upper electrode 146. The gate electrode G and the upper electrode 146 overlapping each other, with the second insulating layer 109 therebetween, may form the storage capacitor Cst. In one or more embodiments, the gate electrode G may be the lower electrode 144 of the storage capacitor Cst. In other embodiments, the lower electrode 144 of the storage capacitor Cst may be included as an independent component.

The upper electrode 146 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may include a single layer or multiple layers, including the above-described material.

A third insulating layer 111 may cover the upper electrode 146. The third insulating layer 111 may include an inorganic insulating material such as silicon oxide (SiO_{X}), silicon nitride (SiN_{X}), silicon oxynitride (SiO_{X}N_{Y}), aluminum oxide (Al₂O₃), titanium oxide (TiO₂), tantalum oxide (Ta₂O₅), hafnium oxide (HfO₂), and/or zinc oxide (ZnO₂), and/or the like. The third insulating layer 111 may include a single layer or multiple layers including the above-described inorganic insulating material.

The source electrode S and the drain electrode D may be on the third insulating layer 111. The source electrode S and the drain electrode D may include a conductive material including molybdenum (Mo), aluminum (Al), copper (Cu), titanium (Ti), and/or the like, and may be formed as a multi-layer or single-layer structure including the above material. In one or more embodiments, the source electrode S and the drain electrode D may have a multi-layer structure including titanium (Ti)/aluminum (AD/titanium (Ti).

A planarization layer 113 may cover the source electrode S and the drain electrode D. The planarization layer 113 may have a flat upper surface such that a pixel electrode 121 on the planarization layer 113 may be flat.

The planarization layer 113 may include an organic material and/or an inorganic material and may have a single-layer structure or a multi-layer structure. The planarization layer 113 may include a general-purpose polymer such as benzocyclobutene (BCB), polyimide, hexamethyldisiloxane (HMDSO), PMMA, and/or polystyrene (PS), a polymer derivative having a phenolic group, an acrylic polymer, an imide-based polymer, an aryl ether-based polymer, an amide-based polymer, a fluorine-based polymer, a p-xylene-based polymer, and/or a vinyl alcohol-based polymer. The planarization layer 113 may include an inorganic insulating material such as silicon oxide (SiO_{X}), silicon nitride (SiN_{X}), silicon oxynitride (SiO_{X}N_{Y}), aluminum oxide (Al₂O₃), titanium oxide (TiO₂), tantalum oxide (Ta₂O₅), hafnium oxide (HfO₂), and/or zinc oxide (ZnO₂), and/or the like. When forming the planarization layer 113, chemical mechanical polishing may be performed on the upper surface of the planarization layer 113 in order to provide a flat upper surface after forming the planarization layer 113.

The planarization layer 113 may have a through hole exposing one selected from the source electrode S and the drain electrode D of the thin film transistor TFT. The pixel electrode 121 may contact the source electrode S or the drain electrode D via the via hole to be electrically connected to the thin film transistor TFT.

In one or more embodiments, the planarization layer 113 may include a first planarization layer and a second planarization layer. In one or more embodiments, the first planarization layer and the second planarization layer may include a same material. In other embodiments, the first planarization layer and the second planarization layer may include different materials. As the planarization layer 113 includes the first planarization layer and the second planarization layer, the level of integration of the display device may be increased.

The pixel electrode 121 may be on the planarization layer 113. The pixel electrode 121 may include a conductive oxide such as indium tin oxide (ITO), indium zinc oxide (IZO), zinc oxide (ZnO), indium oxide (In₂O₃), indium gallium oxide (IGO), and/or aluminum zinc oxide (AZO). The pixel electrode 121 may include a reflective layer including silver (Ag), magnesium (Mg), aluminum (Al), platinum (Pt), palladium (Pd), gold (Au), nickel (Ni), neodymium (Nd), iridium (Ir), chromium (Cr), and/or a compound thereof. For example, the pixel electrode 121 may have a structure in which layers including ITO, IZO, ZnO, and/or In₂O₃ are above or below the above-described reflective layer. In this case, the pixel electrode 121 may have a structure in which ITO/Ag/ITO are stacked.

A pixel defining layer 119 may be on the planarization layer 113. The pixel defining layer 119 may be on the planarization layer 113 and cover edges of the pixel electrode 121. In the pixel defining layer 119, a first opening exposing at least a portion of the pixel electrode 121 may be defined.

The pixel defining layer 119 may increase a distance between the edges of the pixel electrode 121 and an opposite electrode 123 above the pixel electrode 121 to prevent an arc and/or the like (or to reduce an occurrence and/or likelihood thereof) at the edges of the pixel electrode 121. The pixel defining layer 119 may include, for example, an organic insulating material such as polyimide, polyamide, an acrylic resin, benzocylcobutene, HMDSO, a phenolic resin, and/or the like, and may be formed by spin coating, and/or the like.

In one or more embodiments, a spacer to prevent or reduce mask stamping may be further on the pixel defining layer 119. The spacer may be formed as a single body with the pixel defining layer 119. For example, the spacer and the pixel defining layer 119 may be concurrently (e.g., simultaneously) formed in a same process by using a halftone mask process.

An intermediate layer 122 may be in the first opening defined in the pixel defining layer 119, to correspond to the pixel electrode 121. The intermediate layer 122 may include an emission layer. The emission layer may include a polymer material or a low-molecular-weight material, and may emit red, green, blue, or white light.

In one or more embodiments, the intermediate layer 122 may further include an organic functional layer above and/or below the emission layer. The organic functional layer may include a first functional layer and/or a second functional layer. In other embodiments, the first functional layer and/or the second functional layer may be omitted.

The first functional layer may be below the emission layer. The first functional layer may have a single-layer or multi-layer structure including an organic material. The first functional layer may be a hole transport layer (HTL) having a single-layer structure. In one or more embodiments, the first functional layer may include a hole injection layer (HIL) and an HTL.

The second functional layer may be above the emission layer. The second functional layer may be a single layer or multiple layers including an organic material. The second functional layer may include an electron transport layer (ETL) and/or an electron injection layer (EIL).

The opposite electrode 123 may be on the intermediate layer 122. The opposite electrode 123 may include a conductive material having a low work function. For example, the opposite electrode 123 may include a (semi-)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), and/or an alloy thereof. In one or more embodiments, the opposite electrode 123 may further include a layer such as ITO, IZO, ZnO, and/or In₂O₃ on the (semi-) transparent layer including the above-described material.

In one or more embodiments, the layers from the pixel electrode 121 to the opposite electrode 123 may constitute an organic light-emitting diode 120.

A capping layer including an organic material may be formed on the opposite electrode 123. The capping layer may be provided to protect the opposite electrode 123 and also increase light extraction efficiency. The capping layer may include an organic material having a higher refractive index than the opposite electrode 123.

A thin film encapsulation layer 130 may be on the organic light-emitting diode 120 of the display device 1, as an encapsulation member. For example, the organic light-emitting diode 120 may be encapsulated using the thin film encapsulation layer 130. The thin film encapsulation layer 130 may be on the opposite electrode 123. The thin film encapsulation layer 130 may prevent or reduce penetration of external moisture and/or foreign substances from the outside environment into the organic light-emitting diode 120.

The thin film encapsulation layer 130 may include at least one inorganic film layer and at least one organic film layer. In an embodiment, the thin film encapsulation layer 130 may include a first inorganic film layer 131, an organic film layer 132, and a second inorganic film layer 133. In an embodiment, the number of organic encapsulation layers and the number of inorganic encapsulation layers, and the stacking order thereof, may be modified.

The first inorganic film layer 131 and the second inorganic film layer 133 may include at least one inorganic insulating material such as silicon oxide (SiO_{X}), silicon nitride (SiN_{X}), silicon oxynitride (SiON), aluminum oxide (Al₂O₃), titanium oxide (TiO₂), tantalum oxide (Ta₂O₅), hafnium oxide (HfO₂), and/or zinc oxide (ZnO₂), and may be formed using a chemical vapor deposition (CVD) method and/or the like. The organic film layer 132 may include a polymer-based material. Examples of the polymer-based material may include a silicon-based resin, an acrylic resin, an epoxy resin, polyimide, polyethylene, and/or the like.

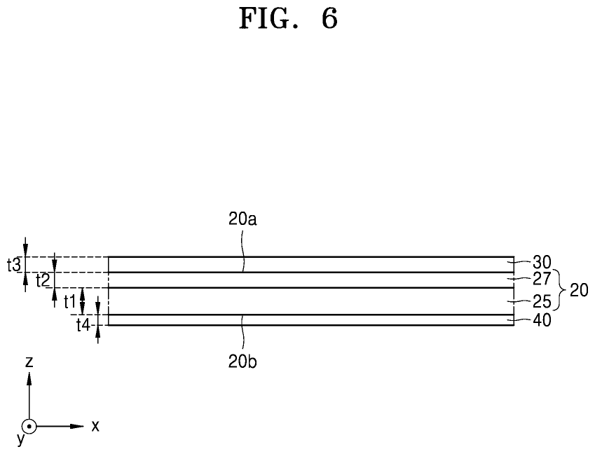

FIGS. 6 through 10 are cross-sectional views schematically illustrating methods of manufacturing a cover window, according to one or more embodiments.

Hereinafter, a method of manufacturing the cover window 10 will be described sequentially by referring to FIGS. 6 through 10.

In one or more embodiments, the method of manufacturing the cover window 10, the cover window 10 having at least one flat portion and at least one curved portion, may include forming a hard coating layer 30 having a thickness of about 20 μm to about 50 μm on a first surface 20a of a window substrate 20, and molding the window substrate 20 on which the hard coating layer 30 is formed.

Referring to FIG. 6, the window substrate 20 may include a first layer 25 and a second layer 27 having a greater hardness than the first layer 25. In an embodiment, the first layer 25 and the second layer 27 may include a same material. In an embodiment, the first layer 25 and the second layer 27 may include different materials. For example, the first layer 25 may include PC, and the second layer 27 may include PMMA. Further, the first layer 25 may include PC, and the second layer 27 may include high hardness PC.

In one or more embodiments, the first layer 25 of the window substrate 20 may have a first thickness t1. The first thickness t1 of the first layer 25 may be about 550 μm to about 800 μm. In an embodiment, the second layer 27 of the window substrate 20 may have a second thickness t2. The second thickness t2 of the second layer 27 may be about 30 μm to about 60 μm.

The hard coating layer 30 may be formed on the window substrate 20. The hard coating layer 30 may be formed on the first surface 20a of the window substrate 20. The hard coating layer 30 may be formed directly on the second layer 27 of the window substrate 20.

In one or more embodiments, a hardness of the hard coating layer 30 may be greater than that of the window substrate 20. However, in one or more embodiments, a hardness of the hard coating layer 30 may be equal to or smaller than that of the window substrate 20.

In one or more embodiments, the hard coating layer 30 may have a third thickness t3. The third thickness t3 of the hard coating layer 30 may be about 20 μm to about 50 μm.

In one or more embodiments, the hard coating layer 30 may include polysilsesquioxane. The hard coating layer 30 may have low viscosity. For example, the polysilsesquioxane of the hard coating layer 30 may have a viscosity of about 10 centipoise (cP) to about 30 cP. As the hard coating layer 30 has a low viscosity, the hard coating layer 30 may be formed flat on the window substrate 20.

A lower coating layer 40 may be formed on the second surface 20b of the window substrate 20, opposite the first surface 20a of the window substrate 20. The lower coating layer 40 may be formed directly under the first layer 25 of the window substrate 20.

In one or more embodiments, a hardness of the lower coating layer 40 may be greater than that of the window substrate 20. However, in other embodiments, a hardness of the lower coating layer 40 may be equal to or smaller than that of the window substrate 20.

In one or more embodiments, the lower coating layer 40 may have a fourth thickness t4. The fourth thickness t4 of the lower coating layer 40 may be about 10 μm. In an embodiment, the lower coating layer 40 may be omitted.

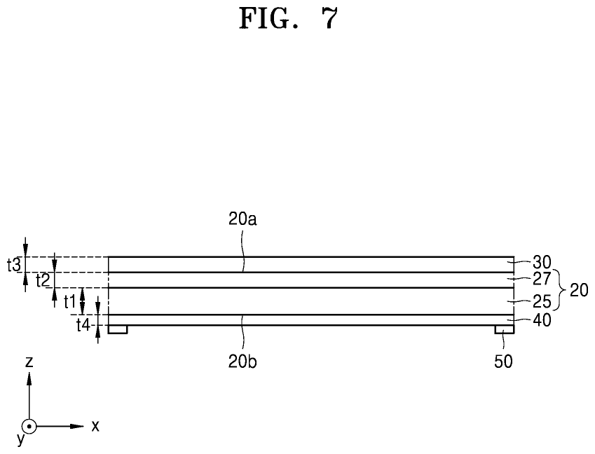

Referring to FIG. 7, after the forming of the hard coating layer 30 on a first surface 20a of the window substrate 20, forming of a light blocking member 50 on a second surface 20b of the window substrate 20, opposite the first surface 20a, may be further performed. In more detail, the light blocking member 50 may be on a lower surface of the lower coating layer 40.

The light blocking member 50 may be formed to correspond to a non-display area of the display panel below the light blocking member 50. As the light blocking member 50 is formed to correspond to the non-display area of the display panel below, components in the non-display area of the display panel may be prevented from being viewed by users, or their visibility to users may be reduced.

In one or more embodiments, the light blocking member 50 may surround an outer portion of the cover window 10. Thus, the light blocking member 50 may have a hole corresponding to a display area of the display panel below.

In one or more embodiments, the light blocking member 50 may include a black matrix. In an embodiment, the black matrix may include at least one of a black pigment, a black dye, and/or black particles. In addition, the black matrix may include, for example, Cr and/or CrO_{X}, Cr/CrO_{X}, Cr/CrO_{X}/CrN_{Y}, a resin (carbon pigment, RGB mixed pigment), graphite, a Non-Cr-based material, and/or the like.

In one or more embodiments, the hard coating layer 30 may be formed on a first surface of a material such as PC and PMMA, and then a light blocking member may be formed on a second surface opposite to the first surface of the material. The material on which the hard coating layer 30 and the light blocking member are formed may be processed by computer numerical control (CNC) to form a plurality of window substrates 20.

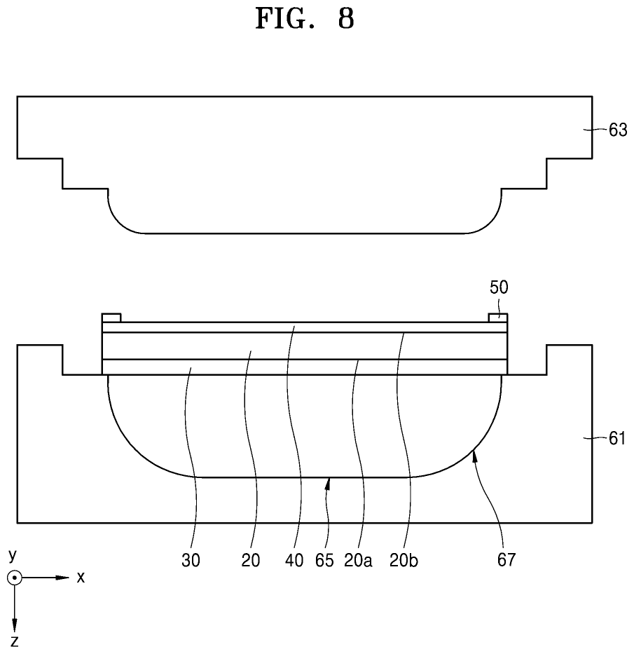

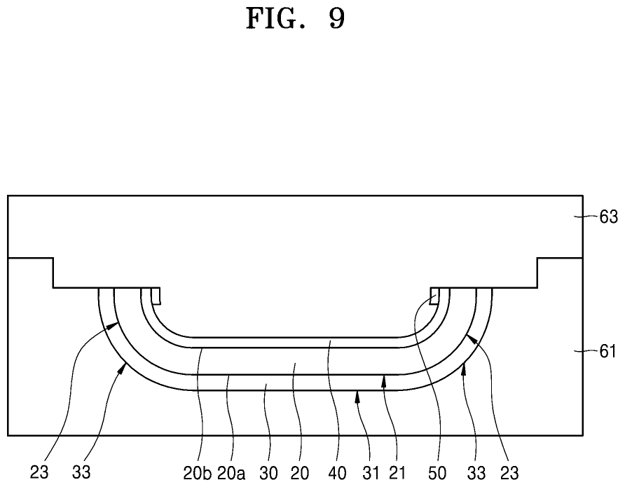

Next, as illustrated in FIGS. 8 and 9, the window substrate 20 may be molded on first surface of which the hard coating layer 30 is formed.

While the window substrate 20 is illustrated as a single layer for convenience of description and illustration in FIGS. 8 and 9, the window substrate 20 of FIGS. 8 and 9 may be included as the first layer 25 and the second layer 27 as described above.

In one or more embodiments, the molding of the window substrate 20 on which the hard coating layer 30 is formed may include positioning the window substrate 20 on which the hard coating layer 30 is formed on a lower mold 61, maintaining the molding room at vacuum, supplying nitrogen into the molding room, and pressurizing the window substrate 20 on which the hard coating layer 30 is formed by using an upper mold 63.

In one or more embodiments, the lower mold 61 may have a same shape as the cover window 10 to be formed. For example, the lower mold 61 may include a flat portion 65 and a curved portion 67, respectively corresponding to the flat portion 11 (FIG. 1) and the curved portion 13 (FIG. 1) of the cover window 10.

In one or more embodiments, the lower mold 61 and the upper mold 63 may include graphite.

In one or more embodiments, in positioning the window substrate 20 on which the hard coating layer 30 is formed on the lower mold 61; the window substrate 20 on which the hard coating layer 30 is formed may be located such that the first surface 20a of the window substrate 20 is located at the lower mold 61, and the second surface 20b of the window substrate 20 is located at the upper mold 63.

Next, impurities in the molding room may be completely removed by completely discharging the air from the molding room while maintaining the molding room at a vacuum. Further, by supplying nitrogen gas into the molding room, the molding room may be maintained in a nitrogen atmosphere.

As illustrated in FIG. 9, by allowing the lower mold 61 and the upper mold 63 to engage with each other, the window substrate 20 on which the hard coating layer 30 is formed may be pressurized. In pressurizing of the window substrate 20 on which the hard coating layer 30 is formed, the window substrate 20 on which the hard coating layer 30 is formed may be pressurized at a temperature of about 120° C. to about 130° C. for three to five minutes.

As the window substrate 20 on which the hard coating layer 30 is formed is pressurized at a temperature of about 120° C. to about 130° C. for three to five minutes, the hard coating layer 30 and/or the window substrate 20 may thermally formed.

As the glass transition temperature Tg of PC and PMMA included in the window substrate 20 is 120° C., when a thermal forming temperature of the window substrate 20 is lower than 120° C., the window substrate 20 may be broken or cracked, degrading the molding properties. On the other hand, when a thermal forming temperature of the window substrate 20 is higher than 130° C., hardness of PC and PMMA included in the window substrate 20 and/or hardness of polysilsesquioxane included in the hard coating layer 30 may be lowered, or the curved portions may be cracked.

Accordingly, when the window substrate 20 on which the hard coating layer 30 is formed is thermally formed at a temperature of 120° C. to 130° C., breaking or cracking of the window substrate 20 may be prevented or reduced, and the cover window 10 obtained through the manufacture may have a hardness of 3H or greater or 4H or greater, thereby increasing scratch resistance of the cover window 10.

When a period of time of thermal forming of the window substrate 20 on which the hard coating layer 30 is formed is less than three minutes, the molding properties may be degraded and the window substrate 20 may be released back to its shape before the thermal forming. On the other hand, when a period of time of thermal forming of the window substrate 20 on which the hard coating layer 30 is formed is longer than five minutes, the window substrate 20 and/or the hard coating layer 30 may be broken.

Thus, when a period of time of thermal forming of the window substrate 20 on which the hard coating layer 30 is formed satisfies three to five minutes, breaking or cracking of the window substrate 20 may be prevented or reduced and the molding properties of the window substrate 20 may be improved at the same time.

By thermally forming the window substrate 20 on which the hard coating layer 30 is formed, by pressurizing the window substrate 20 at a temperature of about 120° C. to about 130° C. for three to five minutes, at least one first flat portion 21 and at least one first curved portion 23 may be formed in the window substrate 20 on which the hard coating layer 30 is formed, and at least one second flat portion 31 and at least one second curved portion 33 may be formed in the hard coating layer 30.

In a present embodiment, the at least one first curved portion 23 formed in the window substrate 20 and the at least one second curved portion 33 formed in the hard coating layer 30 may be curved toward the second surface 20b of the window substrate 20.

In one or more embodiments, the upper mold 63 may have a same shape as the cover window 10 to be formed. For example, the upper mold 63 may include a flat portion 65 and a curved portion 67 respectively corresponding to the flat portion 11 (FIG. 1) and the curved portion 13 (FIG. 1) of the cover window 10.

In one or more embodiments, the window substrate 20 on which the hard coating layer 30 is formed may be located such that the first surface 20a of the window substrate 20 is located at the upper mold 63, and the second surface 20b of the window substrate 20 is located at the lower mold 61. In an embodiment, after locating the window substrate 20 on which the hard coating layer 30 is formed such that the first surface 20a of the window substrate 20 is located at the upper mold 63 and the second surface 20b of the window substrate 20 is located at the lower mold 61, the lower mold 61 and the upper mold 63 may be engaged with other to pressurize the window substrate 20 on which the hard coating layer 30 is formed.

Accordingly, the at least one first flat portion 21 and the at least one first curved portion 23 may be formed in the window substrate 20, and the at least one second flat portion 31 and the at least one second curved portion 33 may be formed in the hard coating layer 30. The at least one first curved portion 23 formed in the window substrate 20 and the at least one second curved portion 33 formed in the hard coating layer 30 may be curved toward the second surface 20b of the window substrate 20.

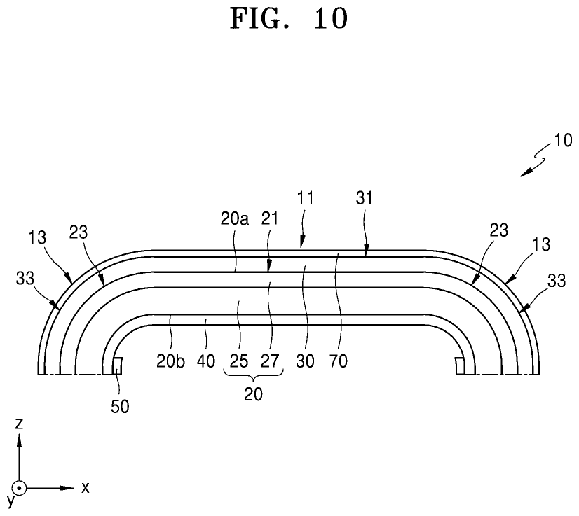

Referring to FIG. 10, after the molding the window substrate 20 on which the hard coating layer 30 is formed, forming a functional coating layer 70 on the hard coating layer 30 may be subsequently performed. In an embodiment, the functional coating layer 70 may be an anti-fingerprint (AF) coating layer.

When the window substrate 20 includes glass, and the window substrate 20 is molded to form at least one curved portion in the window substrate 20, there may be problems such as breaking of the window substrate 20, for example.

In one or more embodiments, because the window substrate 20 is included using a polymer resin, even when forming at least one curved portion in the window substrate 20 by molding the window substrate 20, breaking of or damage to the window substrate 20 may be prevented or reduced.

In one or more embodiments, as the window substrate 20 includes the first layer 25 and the second layer 27, and the first layer 25 includes PC and the second layer 27 includes PMMA having a higher hardness than PC, the hardness of the window substrate 20 may be increased.

In one or more embodiments, by arranging, on the window substrate 20, the hard coating layer 30 having a higher hardness than the window substrate 20, the molding properties of the cover window 10 may be improved, and the hardness of the cover window 10 may be increased.

When forming a coating layer on the window substrate 20 after forming at least one curved portion by molding the window substrate 20, a coating layer may be irregularly formed on the at least one curved portion. In addition, after coating the window substrate 20 with an acrylic material, and forming at least one curved portion by molding the window substrate 20, cracks may be generated in the curved portion.

In one or more embodiments, by forming the hard coating layer 30, including polysilsesquioxane, on the window substrate 20, and then forming at least one curved portion by molding the window substrate 20, cracks may be prevented or reduced in the curved portion, and also, the hard coating layer 30 in the curved portion may also have a uniform (e.g., substantially uniform) thickness.

According to the embodiments of the present disclosure as described above, by forming a coating layer on a window substrate and then molding the window substrate on which the coating layer is formed, cracks in a curved portion may be prevented or reduced. However, the scope of the present disclosure is not limited by the above-described effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the present disclosure as defined by the following claims, and equivalents thereof.

What is claimed is:

1. A method of manufacturing a cover window having at least one flat portion and at least one curved portion, the method comprising:
forming a hard coating layer having a thickness of about 20 μm to about 50 μm, on a first surface of a window substrate; and
molding the window substrate on which the hard coating layer is formed,
wherein the molding of the window substrate on which the hard coating layer is formed comprises forming at least one first flat portion and at least one first curved portion in the window substrate.

2. The method of claim 1, wherein the forming of the hard coating layer on the first surface of the window substrate further comprises forming a first layer comprising polycarbonate and forming a second layer comprising polymethyl methacrylate on the first layer.

3. The method of claim 2, wherein the first layer has a thickness of about 550 μm to about 880 μm.

4. The method of claim 2, wherein the second layer has a thickness of about 30 μm to about 60 μm.

5. The method of claim 1, wherein the hard coating layer comprises polysilsesquioxane.

6. The method of claim 5, wherein the polysilsesquioxane has a viscosity of about 10 centipoise (cP) to about 30 cP.

7. The method of claim 1, wherein a hardness of the hard coating layer is higher than a hardness of the window substrate.

8. The method of claim 1, further comprising forming a light blocking member on a second surface of the window substrate opposite the first surface of the window substrate after the forming of the hard coating layer.

9. The method of claim 1, wherein the molding of the window substrate comprises thermally forming the window substrate at a temperature of about 120° C. to about 130° C. and for about three minutes to about five minutes.

10. The method of claim 1, wherein the molding of the window substrate further comprises forming at least one second flat portion and at least one second curved portion in the hard coating layer.

11. The method of claim 1, further comprising forming a functional coating layer on the hard coating layer after the molding of the window substrate.

12. A cover window comprising at least one flat portion and at least one curved portion, the cover window comprising:
a window substrate comprising at least one first flat portion and at least one first curved portion; and
a hard coating layer comprising at least one second flat portion and at least one second curved portion, wherein the hard coating layer is on a first surface of the window substrate and has a thickness of about 20 μm to about 50 μm.

13. The cover window of claim 12, wherein the window substrate comprises a first layer comprising polycarbonate and a second layer comprising polymethyl methacrylate on the first layer.

14. The cover window of claim 13, wherein the first layer has a thickness of about 550 μm to about 880 μm.

15. The cover window of claim 13, wherein the second layer has a thickness of about 30 μm to about 60 μm.

16. The cover window of claim 12, wherein the hard coating layer comprises polysilsesquioxane.

17. The cover window of claim 12, wherein a hardness of the hard coating layer is greater than a hardness of the window substrate.

18. The cover window of claim 12, further comprising a functional coating layer on the hard coating layer.

19. The cover window of claim 12, further comprising a lower coating layer on a second surface of the window substrate opposite the first surface of the window substrate.

20. A display device comprising:
a display panel; and
a cover window above the display panel and comprising at least one flat portion and at least one curved portion,
wherein the cover window comprises:
a window substrate comprising at least one first flat portion and at least one first curved portion; and
a hard coating layer comprising at least one second flat portion and at least one second curved portion, the hard coating layer being on a first surface of the window substrate and having a thickness of about 20 μm to about 50 μm.
